(19) United States
(12) Patent Application Publication
(10) Pub. No.: US 2009/0250251 A1
(43) Pub. Date: Oct. 8, 2009

(54) Circuit Device and Method for Manufacturing the Circuit Device

(76) Inventors: Kiyoshi Shibata, Gifu (JP); Ryosuke Usui, Aichi (JP); Yasunori Inoue, Gifu (JP)

Correspondence Address: MCDERMOTT WILL & EMERY LLP, 600 13TH STREET, N.W., WASHINGTON, DC, 20005-3096, US

(21) Appl. No.: 12/085,822

(22) PCT Filed: Nov. 30, 2006
(86) PCT No.: PCT/JP2006/323972

§ 371 Date: Oct. 8, 2008

(30) Foreign Application Priority Data
Nov. 30, 2005 (JP) 2005-347284

(51) Int. Cl. H05K 1/02; H05K 1/11; H05K 3/32

(52) U.S. Cl. 174/255; 174/262; 29/840

(57) ABSTRACT

In a circuit device where a wiring layer, an insulating resin and a circuit element are stacked together in such a manner as to embed a bump structure into the insulating resin, the connection reliability between the bump structure and the circuit element is enhanced.

A circuit device (10) has a structure where a wiring layer (20), an insulating resin layer (30) and a circuit element (40) are stacked in this order by a pressure bonding. The wiring layer (20) is provided with bump electrodes (22) in positions that correspond respectively to element electrodes of a circuit element (40). The insulating resin layer (30) is formed of a material that develops plastic flow when pressurized. The bump electrode (22) penetrates the insulating resin layer (30) and is electrically connected to a corresponding element electrode (42).

### TECHNICAL FIELD

The present invention relates to a circuit device and a method for manufacturing the circuit device.

### BACKGROUND TECHNOLOGY

In recent years, with miniaturization and higher performance in electronic devices, demand has been ever greater for further miniaturization of circuit devices used in the electronic devices. With such miniaturization of circuit devices, it is of absolute necessity that the pitch of electrodes that allow packaging on wiring substrate be made narrower. A known method of surface-mounting a circuit element is flip chip mounting in which solder bumps are formed on electrodes of a circuit element and the solder bumps are soldered to an electrode pad of a wiring substrate. With the flip chip mounting method, however, there are restrictive factors for the narrowing of the pitch of electrodes, such as the size of the solder bump itself and the bridge formation at soldering. As a structure used to overcome these limitations, known is a structure where a bump structure formed by half-etching a substrate is used as an electrode or a via, and electrodes of a circuit element are connected to the bump structure by mounting the circuit element on the substrate through a insulating resin such as an epoxy resin (See Patent Document 1 and Patent Document 2).

[Patent Document 1] Japanese Patent Application Laid-Open No. Hei09-289264.

[Patent Document 2] Japanese Patent Application Laid-Open No. 2000-68641.

### DISCLOSURE OF THE INVENTION

### Problems to be Solved by the Invention

As in a conventional technology where an epoxy resin is used as the insulating resin, a wiring layer, an insulating resin and a circuit element are stacked together in such a manner that bump structures are embedded in the insulating resin. In such a case, because of a low fluidity of the epoxy resin, a residual film of resin stays on at an interface between the bump structures and the opposing electrodes of the circuit element. This presents a problem of reduced connection reliability.

The present invention has been made in view of the foregoing problems to be resolved, and an objective thereof is to provide a technology for improving the connection reliability between bump structures and electrodes of a circuit element in a circuit device formed by stacking a wiring layer, an insulating resin and a circuit element in such a manner that the bump structures are embedded in the insulating resin.

### Means for Solving the Problems

One embodiment of the present invention relates to a circuit device. This circuit device comprises: a wiring layer provided with a bump electrode; a circuit element provided with an element electrode disposed counter to the bump electrode; and an insulating resin layer, provided between the wiring layer and the circuit element, which develops plastic flow under pressure, wherein the bump electrode penetrates the insulating resin layer by press-bonding the wiring layer to the insulating resin layer so as to electrically connect the bump electrode and the element circuit.

According to this embodiment, the probability that a residual film of insulating resin layer will stay on at an interface between the bump electrode and the element electrode is suppressed. Hence, the connection reliability of the circuit device is improved.

In the above-described embodiment, the bump electrode may have: an upper surface substantially parallel to a contact face of the element electrode; and a side face formed in such a manner that a diameter thereof becomes narrower as the side face approaches the upper surface.

According to this embodiment, the bump electrodes can be penetrated through the insulating resin layer smoothly when the wiring layer, the insulating resin layer and the circuit element are stacked together by the press-bonding.

In the above-described embodiment, the degree to which the diameter of the bump electrode becomes narrower toward the upper surface may be higher in a top edge than in area other than the top edge. According to this embodiment, the area of interface between the bump electrode and the insulating resin layer increases and therefore the adhesion between the bump electrodes and the insulating resin layer can be improved. In the above-described embodiment, the circuit device may have a plurality of the circuit elements.

Another embodiment of the present invention relates to a circuit device. The circuit device comprises: a circuit element; a radiator member provided with a bump; and an insulating resin layer, provided between the radiator member and the circuit element, which develops plastic flow under pressure, wherein the bump penetrates the insulating resin layer by press-bonding the radiator member to the insulating resin layer so as to thermally connect the bump and the circuit element.

Another embodiment of the present invention relates to a method for manufacturing a circuit device. This method for manufacturing a circuit device comprises: a process for forming a bump electrode on a metal sheet; and a process for press-bonding the metal sheet and a circuit element, provided with an element electrode corresponding to the bump electrode, via an insulating resin layer that develops plastic flow under pressure and electrically connecting the bump electrode and the element electrode in such a manner that the bump electrode penetrates the insulating resin layer.

In the above-described process for forming a bump electrode, a shape of the bump electrode may be formed in such a manner that a diameter thereof becomes narrower toward an upper surface thereof. Also, in the above-described process for forming a bump electrode, the degree to which the diameter of the bump electrode becomes narrower toward the upper surface may be higher in a top edge than in area other than the top edge.

Optional combinations of the aforementioned constituting elements may also be within the scope of the invention protected by the present patent application.

### EFFECT OF THE INVENTION

According to the present invention, the connection reliability of the bump structures and the electrodes of a circuit element is improved in the circuit device where the wiring layer, the insulating resin and the circuit element are stacked together in such a manner that the bump structures are embedded in the insulation resin.

### BRIEF DESCRIPTION OF THE DRAWINGS

FIG. 1 is a cross-sectional view showing a structure of a circuit device according to a first embodiment.

FIG. 2 are cross-sectional views showing a process in a method for forming bump electrodes.

FIGS. 3(A) to 3(C) are cross-sectional views showing a process in a method for connecting bump electrodes and element electrode and forming a wiring layer.

FIGS. 4(A) to 4(C) are cross-sectional views showing a process in a method for connecting bump electrodes and element electrodes and forming a wiring layer.

FIG. 5 is a cross-sectional view showing how tip ends of bump electrodes bite into element electrodes.

FIG. 6 is a cross-sectional view showing a structure of a circuit device according to a second embodiment.

FIG. 7(A) is a perspective view of a circuit device, viewed from a chip side thereof, according to a third embodiment. FIG. 7(B) is a perspective view of the circuit device, viewed from a wiring side thereof, according to a third embodiment. FIG. 7(C) is a cross-sectional view taken along line A-A′ of FIG. 7(A) and line B-B′ of FIG. 7(B).

FIGS. 8(A) to 8(E) are cross-sectional views showing a process in a method for manufacturing a circuit device according to a third embodiment.

FIGS. 9(A) to 9(C) are cross-sectional views showing a process in a method for manufacturing a circuit device according to a third embodiment.

FIG. 10(A) is a cross-sectional view showing a structure of a circuit device according to a fourth embodiment. FIG. 10(B) is an enlarged view of major parts in a section enclosed by a dotted line C of FIG. 10(A).

### DESCRIPTION OF THE REFERENCE NUMERALS

10 Circuit device, 20 Wiring layer, 22 Bump electrode, 24 Copper sheet, 26 Solder bump, 30 Insulating resin layer, 40 Circuit element, 42 Element electrode

### BEST MODE FOR CARRYING OUT THE INVENTION

Embodiments of the present invention will be described by reference to the Figures.

### First Embodiment

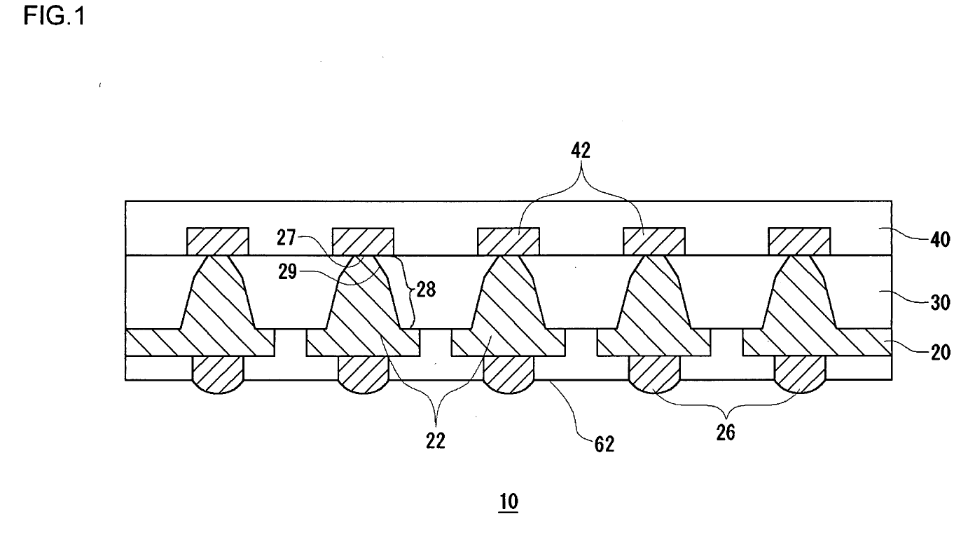

FIG. 1 is a cross-sectional view showing a structure of a circuit device 10 according to a first embodiment. The circuit device 10 includes a wiring layer 20, an insulating resin layer 30, and a circuit element 40, which are stacked in this order.

The wiring layer 20 is formed of a metal member such as copper, and includes a predetermined wiring pattern. Bump electrodes 22 are provided in positions corresponding respectively to element electrodes 42 of the circuit element 40. Solder bumps 26 are provided on an outer-surface side of area where the bump electrodes 22 are formed, respectively.

A bump electrode 22 has an upper face part 27 substantially parallel to a contact face of an element electrode 42 described later, and a side portion 28 formed in such a manner that the diameter thereof tapers toward the upper face 27. In the bump electrode 22 according to the present embodiment, the degree to which the diameter of the bump electrode 22 tapers toward the upper face 27 is higher in a top edge 29 than in parts other than the top edge 29. Thereby, the area of interface between the bump electrode 22 and the insulating resin layer 30 increases. As a result, the adhesion between the bump electrodes 22 and the insulating resin layer 30 improves and therefore the reliability of the circuit device 10 improves. In the present embodiment, exemplified is the bump electrode 22 having a cross section shape where both corners of the top edge of a trapezoid having the upper face part 27 as an upper side are removed. The bump electrode 22 penetrates the insulating resin layer 30 and is electrically connected to the element electrode 42 disposed in the circuit element 40.

The insulating resin layer 30 is provided between the wiring layer 20 and the circuit element 40. One face of the insulating resin layer 30 is press-bonded to the wiring layer 20, whereas the other face thereof is press-bonded to the circuit element 40. The insulating resin layer 30 is made of a material that develops plastic flow when pressurized. An example of the material that develops plastic flow when pressurized is epoxy thermosetting resin. The epoxy thermosetting resin to be used for the insulating resin layer 30 may be, for example, one having viscosity of 1 kPa·s under the conditions of a temperature of 160° C. and a pressure of 8 MPa. If a pressure of 15 MPa is applied to this material at a temperature of 160° C., then the viscosity of the resin will drop to about ⅛ of that before the pressurization. In contrast to this, an epoxy resin in B stage before thermosetting has no viscosity similarly to a case when the resin is not pressurized, and the epoxy resin develops no viscosity even when pressurized under a condition that the temperature is below a glass transition temperature Tg.

The circuit element 40 is press-bonded to the insulating resin layer 30 in a manner such that an electrode surface of the circuit element 40 provided with the element electrodes 42 is disposed toward an insulating resin layer 30 side. A specific example of the circuit element 40 is a semiconductor chip such as an integrated circuit (IC) or a large-scale integrated circuit (LSI).

An outer surface of area in the wiring layer 20 where no solder bump 26 is provided and an outer surface of area in the insulating resin layer 30 where no wiring layer 20 is formed are covered with solder resists 62. When the solder bumps 26 are bonded to a mounting board through the solder resists 62 by the use of a reflow process or the like, damage to the wiring layer 20 and the insulating resin layer 30 due to the heat is regulated.

A material that develops plastic flow when pressured is used for the insulating resin layer 30 in the circuit device 10 according to the present embodiment. As a result, when the wiring layer 20, the insulating resin layer 30, and the circuit element 40 are press-bonded in this order and united into one body, the probability that a residual film of insulating resin layer 30 will stay on at an interface between the bump electrode 22 and the element electrode 42 is suppressed. Hence, the connection reliability is improved.

### Method for Manufacturing a Circuit Device

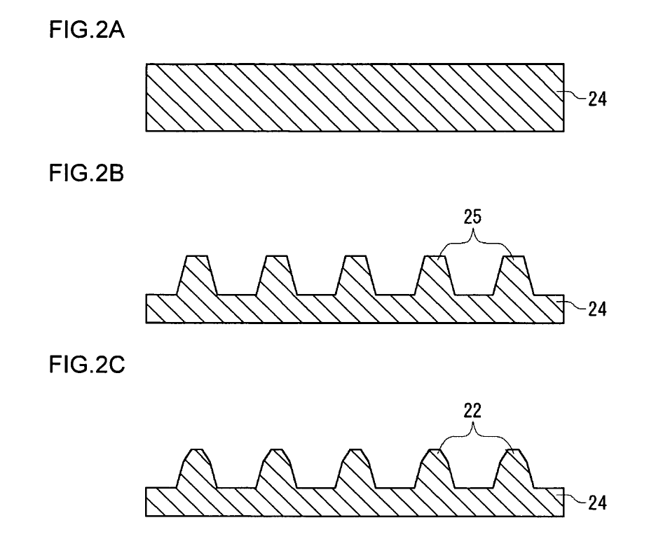

FIG. 2(A) to FIG. 2(C) are cross-sectional views showing a process in a method for forming the bump electrodes 22.

As shown in FIG. 2(A), a copper sheet 24 having the thickness at least larger than the sum of the height of the bump electrode 22 and the thickness of the wiring layer 20 is prepared first. In the present embodiment, the thickness of the copper sheet 24 is 125 μm.

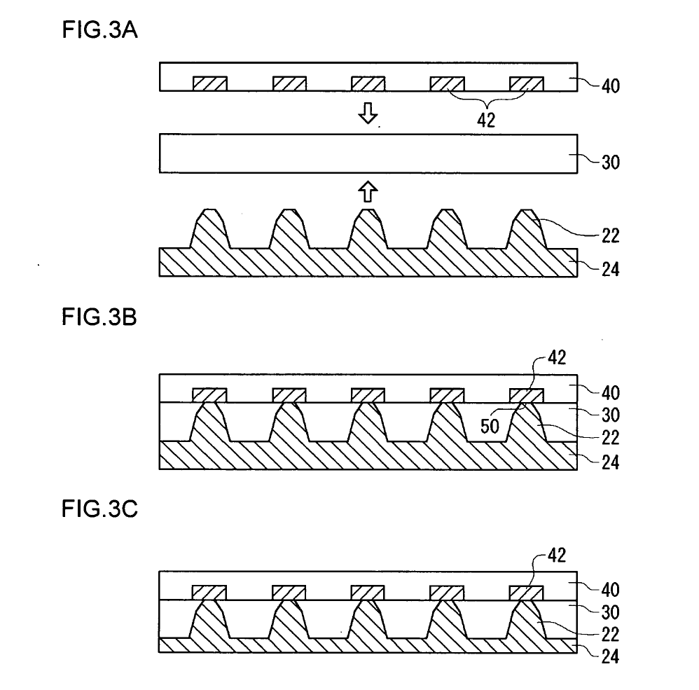

Then, as shown in FIG. 2(B), a resist (not shown) is selectively formed on an electrode forming area by a lithography method, and bumps 25 of a predetermined pattern is formed on the copper sheet 24 using the resist as a mask. The bumps 25 are provided in positions corresponding respectively to the positions of element electrodes 42 formed on the circuit element 40 (See FIG. 3(A)).

Next, as shown in FIG. 2(C), edges on the top part of the bumps 25 are removed by an argon (Ar) sputter so as to form the bump electrodes 22. The height, the diameter of the top face and the diameter of the ground plane of the bump electrode 22 according to the present embodiment are 60 μm, 20 μmφ and 60 μmφ, respectively.

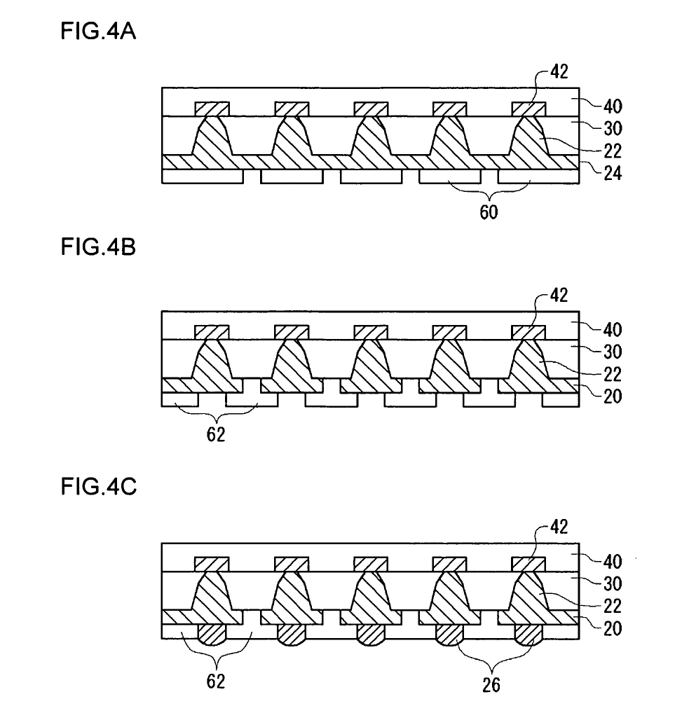

FIGS. 3(A) to 4(C) are cross-sectional views showing a process in a method for connecting the bump electrodes 22 and the element electrodes 42 and forming the wiring layer 20.

As shown in FIG. 3A, an insulating resin 30 is held between a circuit element 40 where the element electrodes 42 having predetermined patterns are formed and a copper sheet 24 where the bump electrodes 22 are built thereinto using the above-described method. The film thickness of the insulating resin layer 30 is approximately equal to the height of the bump electrode 22. The circuit element 40, the insulating resin layer 30 and the copper sheet 24 are press-formed by a press machine into a single block. The pressure and the temperature for the press-forming are about 15 MPa and 180° C., respectively. The press-forming causes the bump electrodes 22 to penetrate the insulating resin layer 30, thus electrically coupling the bump electrodes 22 with the element electrodes 42. The bump electrode 22, which has a side portion formed with increasingly smaller diameter toward the top face portion, penetrates the insulating resin layer 30 smoothly.

The pressure upon press-forming causes a drop in viscosity of the insulating resin layer 30, which sets off plastic flow therein. As a result, the insulating resin layer 30 is pushed out of an interface 50 between the bump electrode 22 and the element electrode 42, thus making it harder for part of the insulating resin layer 30 to remain at the interface 50 (See FIG. 3(B)).

As illustrated in FIG. 3(C), the copper sheet 24 is adjusted into the thickness of a rewiring layer by etching the whole of the opposite side of the copper sheet 24. The thickness of the wiring layer according to this embodiment is 35 μm.

Next, as illustrated in FIG. 4(A), resists 60 are selectively formed according to a pattern of wiring layer by lithography. More specifically, a resist film of 20 μm thickness is affixed to the copper sheet 24 by a laminator unit, and it is then subjected to a UV irradiation using a photo mask having a wiring layer pattern. After this, the resists in the unexposed areas are removed by a development using a Na₂CO₃ solution, which will selectively form the resists 60 on the copper sheet 24. To improve the adhesion of the resists 60 to the copper sheet 24, it is desirable that a pretreatment, such as grinding, cleaning and the like, be performed as appropriate on the surface of the copper sheet 24 before the lamination of the resist film thereon.

As shown in FIG. 4(B), etching is done to an exposed part of the copper sheet 24, using a ferric chloride solution to form a wiring layer 20 having a predetermined wiring pattern. Then the resists are removed using a stripping liquid, such as an NaOH solution. Then while a solder bump forming area is left intact, solder resists 62 are printed on outer surfaces of the wiring layer 20 and the insulating resin layer 30.

Then, as shown in FIG. 4(C), solder bumps 26 are formed on areas of the wiring layer 20 corresponding to the bump electrodes 22.

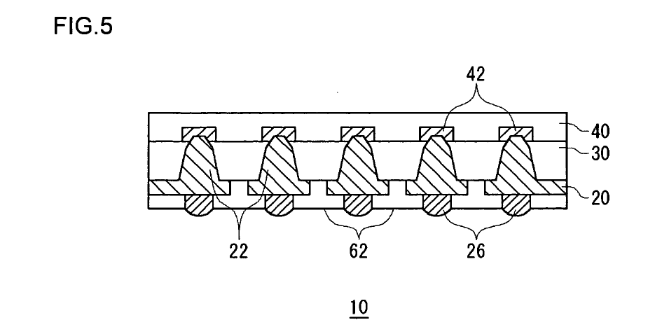

By employing the above-described manufacturing process, a circuit device 10 having a structure as shown in FIG. 1 is obtained. In the above-described circuit device 10, the element electrode 42 is not deformed when the bump electrodes 22 are connected with element electrodes 42 by the press-forming. However, as shown in FIG. 5, tip ends of the bump electrodes 22 may bite into the element electrodes 42. This achieves more reliable electric connection between the bump electrodes 22 and the element electrodes 42, thus further enhancing the connection reliability of the circuit device 10. As shown in FIG. 5, the level of pressure for the press-forming, pressure time or other pressurized conditions may be adjusted to allow the tip ends of the bump electrodes 22 to bite into the element electrodes 42.

### Second Embodiment

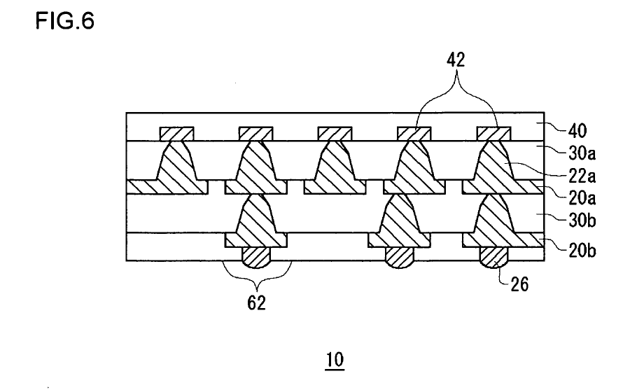

In the above-described first embodiment, the wiring layer 20 has a single layer but it may be multilayered. FIG. 6 is a cross-sectional view showing a structure of a circuit device 10 according to a second embodiment. In the circuit device 10 of the present embodiment, the wiring layer is multilayered.

A method for manufacturing the circuit device 10 according to the second embodiment is basically the same as the method according to the first embodiment. In the method for manufacturing the circuit device 10 according to the second embodiment, a wiring layer 20a and a circuit element 40 are press-bonded through the medium of an insulating resin layer 30a, which is a first layer of insulating resin layers, so as to electrically couple a bump electrode 22a to an element electrode 42. Then, instead of the formation of the solder bump 26 as shown in FIG. 4(C), a wiring layer 20b, which is a second layer of wiring layers, is press-bonded through the medium of an insulating resin layer 30b, which is a second layer of insulating resin layers. By performing the process similar to that shown in FIGS. 2(A) to 2(C), bump electrodes 22b are provided on the wiring layer 20b similarly to the wiring layer 20a. The second wiring layer 20b is press-bonded by repeating the process as shown in FIGS. 3(A) to 4(C). As a result, a bump electrode 22b and the wiring layer 20a are electrically connected.

The above process and arrangement enables achieving further simplified and convenient build-up of multilayered wirings and improving the connection reliability within the multilayered wirings and the connection reliability between the multilayered wirings and the circuit element.

### Third Embodiment

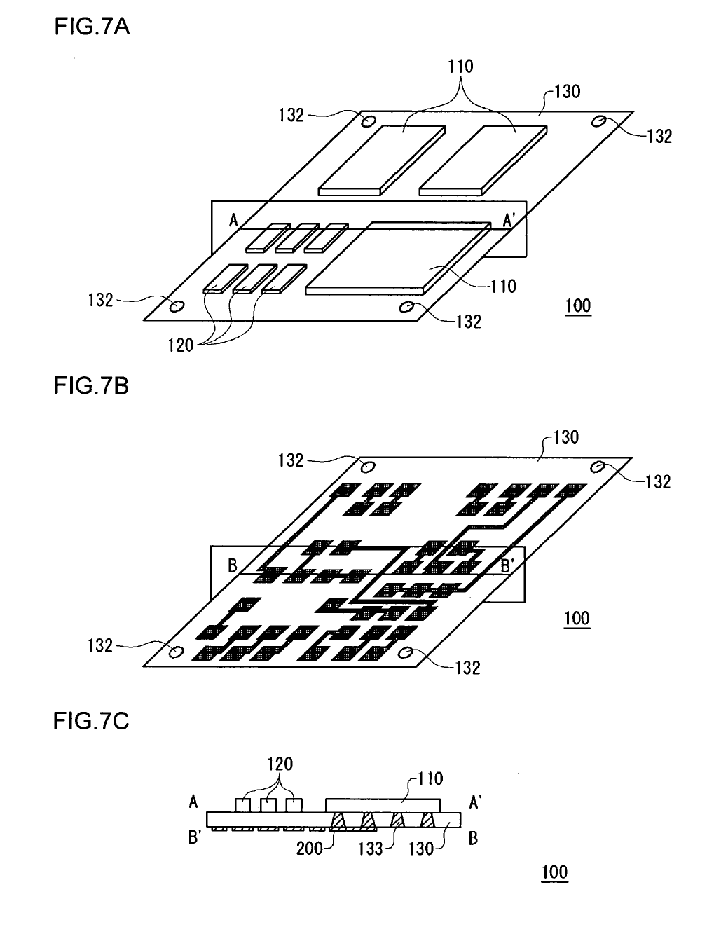

FIG. 7(A) is a perspective view of a circuit device, viewed from a chip side thereof, according to a third embodiment. FIG. 7(B) is a perspective view of the circuit device, viewed from a wiring side thereof, according to the third embodiment. FIG. 7(C) is a cross-sectional view taken along line A-A′ of FIG. 7(A) and line B-B′ of FIG. 7(B).

A circuit device 100 according to the present embodiment is a multi-chip module (MCM) that includes LSIs 110, passive components 120, and an insulating resin layer 130. On the insulating resin layer 130, an alignment mark is provided in a predetermined position. The insulating resin layer 130 is provided with vias (bump electrodes) 133 that penetrate between the both principal surfaces thereof. A plurality of LSIs 110 and passive components 120 are mounted on one principle surface of the insulating resin layer 130, whereas a wiring layer 200 having a predetermined pattern is formed on the other principal surface of the insulating resin layer 130. Note that component members such as bumps are omitted in FIGS. 7(A) to 7(C).

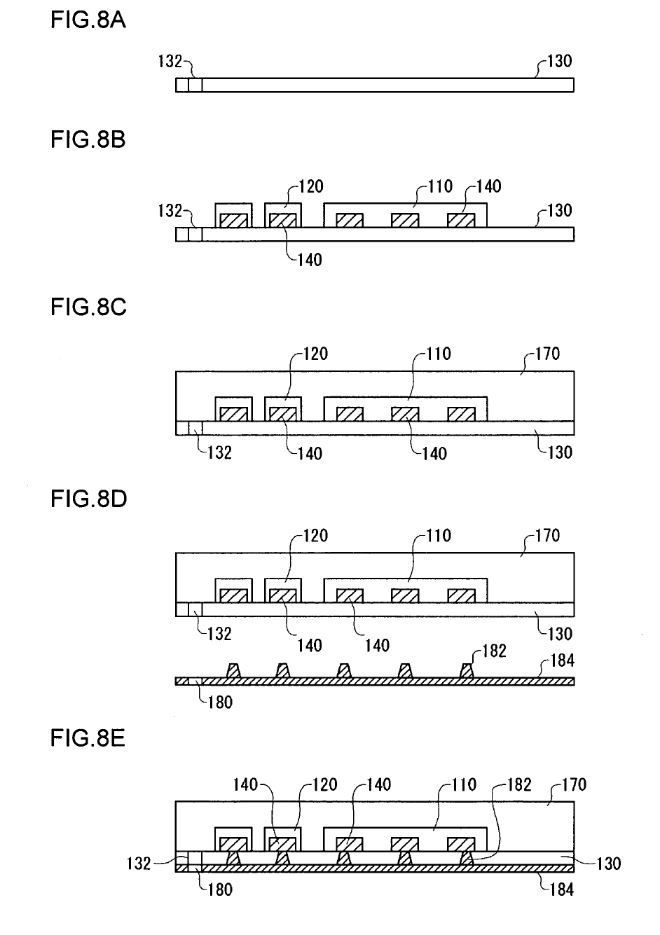

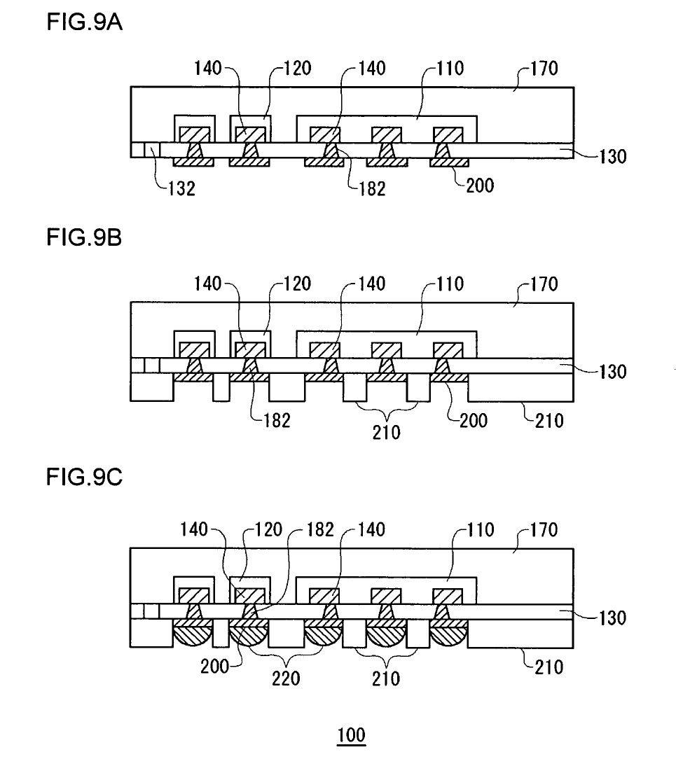

FIGS. 8(A) to 8(E) and FIGS. 9(A) to 9(C) are cross-sectional views showing a process in a method for manufacturing the circuit device 100. As shown in FIG. 8(A), a predetermined area of the insulating resin layer 130 is first drilled by a drill or laser process so as to form an alignment mark 132. The material used for the insulating resin layer 130 is a material that develops plastic flow when pressurized. The film thickness of the insulating resin layer 130 may be 30 μm, for instance.

Next, as shown in FIG. 8(B), pad electrodes 140 are placed in predetermined positions of the insulating resin layer 130. Then the LSIs 110 and the passive components 120 are placed in desired positions on the corresponding pad electrodes using the alignment mark 32. At this time, the LSIs 110 and the passive components 120 are temporarily bonded to the insulating resin layer 130 in a short time of about a few seconds while heated at a temperature (80° C.), for example) to such a degree that the insulating resin layer 130 is not thermally cured.

Then, as shown FIG. 8(C), the insulating resin layer 130, the LSIs 110 and the passive components 120 are packaged by a molded resin 170, using a transfer mold method or the like.

Then, as shown in FIG. 8(D), an alignment mark 180 corresponding to the alignment mark 132 is formed, and a copper sheet 184 where bump electrodes 182 are built thereinto are prepared. Following this, as shown in FIG. 8(E), the alignment mark 180 is aligned with the corresponding alignment mark 132. Hence, the copper sheet 184 is properly positioned, and the pad electrodes 140 and the bump electrodes 182 are bonded together by using a high-precision bonding apparatus. Conditions for the bonding are a pressure of 5 MPa and a temperature of 180° C., for instance.

Then, a dry film resist (not shown) is laminated on the outer surface of the copper sheet 184 and a predetermined pattern of UV (i-ray) is exposed thereon. Then, it is developed using water solution of 0.7% NaCO₃, and a dry film resist is used as a predetermined mask pattern. Further, an exposed part of the copper sheet 184 is etched using a ferric chloride solution to form a wiring layer 200 having a predetermined wiring pattern as shown in FIG. 9(A). Then the dry film resist is removed using the water solution of 2% NaOH.

Then, as shown in FIG. 9(B), a photo solder resist 210 is printed on outer surfaces of the wiring layer 200 and the insulating resin layer 130. The film thickness of the photo solder resist 210 may be 30 mm, for instance.

Next, as shown in FIG. 9(C), bumps 220 are formed on the wiring layer 200 at positions corresponding to the bump electrodes 182. After this, circuit devices 100 can be fabricated by cutting them out into a predetermined size.

### Fourth Embodiment

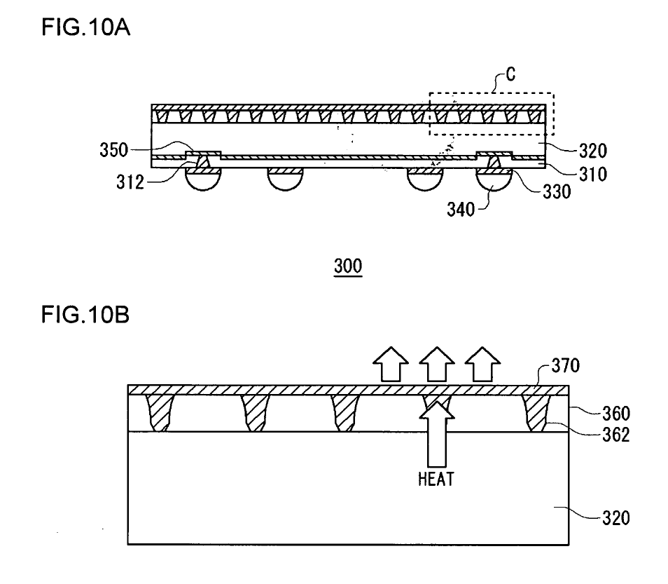

FIG. 10A is a cross-sectional view showing a structure of a circuit device according to a fourth embodiment. FIG. 10(B) is an enlarged view of major parts in a section enclosed by a dotted line C of FIG. 10(A). A circuit device 300 according to the present embodiment is a SoC (System On a Chip) where functions, such as microprocessor, chip set, video chip and memory, are integrated into a single chip (system LSI). Generally speaking, LSIs after 90 nm generation are high heating elements because the leak current rises due to a reduction in gate length.

The circuit device 300 is of such a structure that a system LSI 320 is mounted through the medium of an element electrode 350 provided on one principal surface of an insulating resin layer 310. A wiring layer 330 of a predetermined pattern is formed on the other principal surface of the insulating resin layer 310, and a solder bump 340 is bonded to the wiring layer 330. The wiring layer 330 and the element electrode 350 are electrically connected by a via 312 that penetrates the insulating resin layer 310.

A radiator plate 370 made of a metal such as copper is provided on the system LSI 320 through the medium of the insulating resin layer 360 that develops plastic flow when pressurized. The insulating resin layer 360 is provided with a thermal via 362, so that the radiator plate 370 and the system LSI 320 are thermally connected to each other. As a result, the heat generated in the system LSI 320, which is a high heating element, transfers immediately to the radiator plate 370 and therefore the heat radiation property can be enhanced with a low-cost and simple structure.

The thermal via 362 is a metallic bump formed beforehand on the radiator plate 370. This bump has a side portion, which is formed in such a manner that the diameter is smaller toward the tip end thereof. The radiator plate 370 having the bumps is press-formed by a press machine and thereby the thermal vias 362 that thermally connect the radiator plate 370 to the system LSI 320 can be formed.

The present invention is not limited to the above-described embodiments, and it is understood by those skilled in the art that various modifications such as changes in design may be made based on their knowledge and the embodiments added with such modifications are also within the scope of the present invention.

For example, in the above-described embodiments, the solder bumps are formed on the outermost face of the wiring layer. However, this should not be considered as limiting and, for example, a MOS transistor may be bonded to the outermost layer of wiring layers, and a source electrode, a drain electrode and a gate electrode of the MOS transistor may be electrically connected to the outermost wiring layer.

A means for electrically connecting between different wiring layers through the medium of an insulating resin layer, which develops plastic flow under pressure, using the aforementioned bump electrodes can be applied to a process for manufacturing semiconductor packages, which is called a wafer-level CSP (Chip Size Package) process. The wafer-level CSP process is a technique where steps taken up to the packaging step are performed without cutting the chips for the purpose of making the package size of semiconductor devices nearly identical to the dimensions of semiconductor chips while the state of being a wafer is kept. For example, in the process of forming a rewiring layer in the wafer-level CSP process, the process for structuring a wiring layer where such bump electrodes as described above is formed through the medium of the insulating resin layer made of a material that develops plastic flow under pressure can be repeated as necessary. Thereby, the wafer-level CSP can be made even smaller without deteriorating the connection reliability. Also, the wiring layers can be simply constructed as compared with the conventional semiconductor package manufacturing process. Thus the manufacturing cost of semiconductor packages can be reduced.

### INDUSTRIAL APPLICABILITY

The present invention proves useful in the field of manufacturing a circuit device where a wiring layer, an insulating resin and a circuit element are stacked together.

1. A circuit device, comprising:
a wiring layer provided with a bump electrode;
a circuit element provided with an element electrode disposed counter to the bump electrode; and
an insulating resin layer, provided between the wiring layer and the circuit element, which develops plastic flow under pressure,
wherein the bump electrode penetrates the insulating resin layer by press-bonding the wiring layer to the insulating resin layer so as to electrically connect the bump electrode and the element circuit.

2. A circuit device according to claim 1, the bump electrode having:
an upper surface substantially parallel to a contact face of the element electrode; and
a side face formed in such a manner that a diameter thereof becomes narrower as the side face approaches the upper surface.

3. A circuit device according to claim 2, wherein the degree to which the diameter of the bump electrode becomes narrower toward the upper surface is higher in a top edge than in area other than the top edge.

4. A circuit device according to any one of claim 1 to claim 3, wherein the circuit device has a plurality of the circuit elements.

5. A circuit device, comprising:
a circuit element;
a radiator member provided with a bump; and
an insulating resin layer, provided between the radiator member and the circuit element, which develops plastic flow under pressure,
wherein the bump penetrates the insulating resin layer by press-bonding the radiator member to the insulating resin layer so as to thermally connect the bump and the circuit element.

6. A method for manufacturing a circuit device, the method comprising:
a process for forming a bump electrode on a metal sheet; and
a process for press-bonding the metal sheet and a circuit element, provided with an element electrode corresponding to the bump electrode, via an insulating resin layer that develops plastic flow under pressure and electrically connecting the bump electrode and the element electrode in such a manner that the bump electrode penetrates the insulating resin layer.

7. A method for manufacturing a circuit device according to claim 6, wherein in the process for forming a bump electrode a shape of the bump electrode is formed in such a manner that a diameter thereof becomes narrower toward an upper surface thereof.

8. A method for manufacturing a circuit device according to claim 7, wherein in the process for forming a bump electrode the degree to which the diameter of the bump electrode becomes narrower toward the upper surface is higher in a top edge than in area other than the top edge.
